(19) United States
(12) Patent Application Publication
(10) Pub. No.: US 2006/0239320 A1
(43) Pub. Date: Oct. 26, 2006

(54) Compound semiconductor laser device

(75) Inventor: Yoshinori Ohitsu, Nara-shi (JP)

Correspondence Address: MORRISON & FOERSTER LLP, 1650 TYSONS BOULEVARD, SUITE 300, MCLEAN, VA, 22102, US

(73) Assignee: SHARP KABUSHIKI KAISHA, Osaka (JP)

(21) Appl. No.: 11/398,549

(22) Filed: Apr. 6, 2006

(30) Foreign Application Priority Data
Apr. 21, 2005 (JP) 2005-123869

(51) Int. Cl. H01S 5/00; H01S 3/04

(52) U.S. Cl. 372/46.01; 372/44.01; 372/43.01

(57) ABSTRACT

A compound semiconductor laser device has a semiconductor substrate of first conduction type and a plurality of layers sequentially formed on the substrate. The plurality of layers include first and second cladding layers of the first conduction type, a third cladding layer of second conduction type, and an active layer between the second and third cladding layers. The second cladding layer has a lower carrier concentration than the first cladding layer. For example, the carrier concentration of the first cladding layer is from 1×10¹⁸ cm⁻³ to 2×10¹⁸ cm⁻³, inclusive, and the carrier concentration of the second cladding layer is from 1×10¹⁷ cm⁻³ to 5×10¹⁷ cm⁻³, inclusive.

This nonprovisional application claims priority under 35 U.S.C. §119(a) on Patent Application No. 2005-123869 filed in Japan on Apr. 21, 2005, the entire contents of which are hereby incorporated by reference.

### BACKGROUND OF THE INVENTION

The present invention relates to compound semiconductor laser devices used, for example, as light sources for reading and writing data from and to optical discs.

In recent years, there has been a growing demand for semiconductor laser devices which are used for pickup light sources for media such as CD-ROM (Compact Disc Read Only Memory), CD-R/RW (CD Recordable/Rewritable), DVD-ROM (Digital Versatile Disc Read Only Memory), DVD-R/RW (DVD Recordable/Rewritable). As the spread of commercial products utilizing the above media advances, price reduction of these commercial products proceeds. Following the price reduction of the commercial products, there is a new demand for semiconductor laser devices that are lower in price and that have little characteristic variations and excellent reliability.

When producing, for example, a III-V compound semiconductor laser device representing the above semiconductor laser devices, a stacked layer structure of a plurality of semiconductor layers is formed on a semiconductor substrate. By adding a specified impurity to each semiconductor layer, the electric conduction type or the electric conductivity of each semiconductor layer is controlled to obtain a device of specified semiconductor characteristics. To achieve uniform device characteristics of the semiconductor lasers and improvement in yield of products, it is very important to control the electric conduction type or the electric conductivity of each semiconductor layer to be in conformity with designed values.

As a method of forming III-V compound semiconductor layers, the MOCVD (Metal-Organic Chemical Vapor Deposition) method and the MBE (Molecular Beam Epitaxy) method can be mentioned. When growing a film by using any of these methods, a group IV element such as silicon (Si) and a group VI element such as selenium (Se) are used as impurities for obtaining an n-type III-V compound semiconductor layer. The group IV element becomes a donor impurity by substituting for a group III element of aluminum (Al), gallium (Ga), or indium (In). On the other hand, as an impurity for obtaining a p-type III-V compound semiconductor layer, a group II element such as zinc (Zn), beryllium (Be), or magnesium (Mg) is employed. The group II element becomes an acceptor impurity by replacing a group III element of Al or Ga.

Among semiconductor laser device structures, what we call a self-alignment structure is well known. The fabricating process for a semiconductor laser device of the self-alignment structure will be described below.

First, as shown in FIG. 3A, an n-type GaAs buffer layer 42 (layer thickness: 0.5 μm), an n-type Al_{y}Ga_{1-y)}As first cladding layer 43 (y=0.5, layer thickness: 1.0 μm), a non-doped AlₓGa₍₁₋ₓ₎As active layer 44 (x=0.14, layer thickness: 0.085 μm), a p-type Al_{y}Ga_{(1-y)}As second cladding layer 45 (y=0.5, layer thickness: 0.35 μm) and an n-type GaAs current block layer 46 (layer thickness: 0.6 μm) are successively grown on an n-type GaAs substrate 46 by the MOCVD method. In this stage, Se is employed as the n-type impurity, while Zn, C and the like are employed as the p-type impurity.

Next, as shown in FIG. 3B, an etching mask 47 having a stripe-like groove is formed by a method such as photolithography. Thereafter, a part of the n-type GaAs current block layer 16 is removed in a stripe-like and groove-like shape with a width of 3.5 to 4.0 μm, forming a removed portion 50.

Subsequently, as shown in FIG. 3C, a p-type Al_{y}Ga_{(1-y)}As third cladding layer 48 (y=0.5, layer thickness: 1.0 μm) is grown on the n-type GaAs current block layer 16 and then a p-type GaAs cap layer 49 (layer thickness: 3 to 50 μm) is grown on the p-type Al_{y}Ga_{(1-y)}As third cladding layer 48 by the MOCVD method or the LPE (liquid phase epitaxy) method. In this case, the layer thickness of the p-type GaAs cap layer 49 should be determined as necessary depending on where the final light emitting point of the semiconductor laser device is to be positioned relative to the chip thickness. Zn or Mg is employed then as the p-type impurity for the p-type Al_{y}Ga_{(1-y)}As third cladding layer 48 and the p-type GaAs cap layer 49.

In the semiconductor laser device thus obtained, if Se is used as an impurity added to the n-type Al_{y}Ga_{(1-y)}As first cladding layer 43 and the n-type GaAs current block layer 46, and Zn is used as an impurity added to the p-type Al_{y}Ga_{(1-y)}As second cladding layer 45, these impurities added move or migrate between the layers by diffusion or the interaction of the impurity atoms, resulting in difficulty in obtaining an impurity profile as designed.

In a first method of solving this problem, carbon (C), which has little interaction between impurity atoms, is used as an impurity to be added to the p-type Al_{y}Ga_{(1-y)}As second cladding layer 45, and Mg is used as an impurity to be added to the p-type Al_{y}Ga_{(1-y)}As third cladding layer 48 and the p-type GaAs cap layer 49 (see U.S. Pat. No. 6,618,415 B1).

However, it is not possible to completely suppress diffusion of Se that is the impurity added to the n-type Al_{y}Ga_{(1-y)}As first cladding layer 43 even by the first method, due to a thermal history in growing the p-type Al_{y}Ga_{(1-y)}As third cladding layer 48 and the p-type GaAs cap layer 49 by the LPE method. Furthermore, since Mg that is the impurity added to the p-type Al_{y}Ga_{(1-y)}As third cladding layer 48 and the p-type GaAs cap layer 49 diffuses into a location where a Se carrier concentration has been reduced, there occurs fluctuation in the position of the pn junction, as shown in FIG. 4. In particular, when the n-type Al_{y}Ga_{(1-y)}As first cladding layer 43 has a low Se impurity concentration, there sometimes occurs deterioration in device characteristics of semiconductor lasers such as an increase in threshold current, operating current, operating voltage, etc.

In a second method of reducing diffusion of the impurity added to the n-type Al_{y}Ga_{(1-y)}As first cladding layer 43 due to a thermal history, Si having a small diffusivity is used as an impurity added to the n-type Al_{y}Ga_{(1-y)}As first cladding layer 43 and the n-type current block layer 46, and Mg is used as an impurity added to the p-type Al_{y}Ga_{(1-y)}As third cladding layer 48. In this second method, it is required that the carrier concentration of the p-type Al_{y}Ga_{(1-y)}As third cladding layer 48 be set to about 1×10¹⁸ cm⁻³ to 2×10¹⁸ cm⁻³ in order to obtain good device characteristics of semiconductor lasers. For that reason, in order for Mg, which is the impurity added to the p-type Al_{y}Ga_{(1-y)}As third cladding layer 48, not to reach inside the n-type Al_{y}Ga_{(1-y)}As first cladding layer 43, it is required that the carrier concentration of the n-type Al_{y}Ga_{(1-y)}As first cladding layer 43 be set to fall within a range of 1×10¹⁸ cm⁻³ to 2×10¹⁸ cm⁻³.

However, none of semiconductor laser devices fabricated such that the Si concentration is 1×10¹⁸ cm⁻³ or higher have served as commercial products in terms of long-term reliability. That is, while semiconductor laser devices fabricated by the first method show reliability in the 50,000 hours or longer operations with no practical problem, semiconductor laser devices fabricated by the second method often show deterioration of the characteristics and frequently stop oscillation during the long-term use.

As can be understood from the above, stability in doping control and hence unification of the characteristics, an improvement in yield, and the long-term reliability of devices have not been achieved simultaneously.

### SUMMARY OF THE INVENTION

It is an object of the present invention to provide a compound semiconductor laser device that achieves an increased yield and increased long-term reliability.

In order to accomplish the object, a compound semiconductor laser device according to the present invention comprises:

a semiconductor substrate of first conduction type;

a first cladding layer of the first conduction type formed on the semiconductor substrate;

a second cladding layer of the first conduction type formed on the first cladding layer and having a carrier concentration lower than a carrier concentration of the first cladding layer;

an active layer formed on the second cladding layer; and

a third cladding layer of second conduction type formed on the active layer.

In the present specification, the term “first conduction type” means the p-type or the n-type. Also, the term “second conduction type” means the n-type when the first conduction type is the p-type, and the p-type when the first conduction type is the n-type.

According to the compound semiconductor laser device with the above construction, because the carrier concentration of the second cladding layer is lower than that of the first cladding layer, the second conduction type impurity is prevented from being diffused to the first and second cladding layers, whereby stable doping control of the first and second conduction type impurities is achieved. That is, an impurity profile as designed can be obtained. Therefore, device characteristics of semiconductor laser devices can be unified, and an improvement in production yield of semiconductor laser devices and long-term reliability thereof are both achievable.

Also, because the production yield of semiconductor laser devices is improved, semiconductor laser devices can be fabricated at a lower cost. Accordingly, it is possible to produce semiconductor laser devices having stable characteristics inexpensively and stably.

In one embodiment, the first conduction type is n-type, the second conduction type is p-type, and an impurity in the first cladding layer and the second cladding layer is Si.

In one embodiment, the carrier concentration of the first cladding layer is from 1×10¹⁸ cm⁻³ to 2×10¹⁸ cm⁻³, inclusive, and the carrier concentration of the second cladding layer is from 1×10¹⁷ cm⁻³ to 5×10¹⁷ cm⁻³, inclusive.

In one embodiment, the second cladding layer has a layer thickness in a range of from 10 nm to 50 nm, inclusive.

In one embodiment, the second cladding layer is in proximity to the active layer.

In one embodiment, the semiconductor laser device further comprises a current block layer of the first conduction type formed on the third cladding layer and having a stripe-like and groove-like removed portion; and a fourth cladding layer of the second conduction type formed on the current block layer.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic cross sectional view of a compound semiconductor laser device according to one embodiment of the present invention;

FIG. 2 shows a cross section taken along II-II of FIG. 1 and an impurity concentration profile in the cross section;

FIG. 3A is a schematic cross sectional view showing a fabrication process step of a conventional compound semiconductor laser device;

FIG. 3B is a schematic cross sectional view showing a fabrication process step of the conventional compound semiconductor laser device;

FIG. 3C is a schematic cross sectional view showing a fabrication process step of the conventional compound semiconductor laser device; and

FIG. 4 shows a cross section taken along IV-IV of FIG. 3C and an impurity concentration profile in the cross section.

### DETAILED DESCRIPTION OF THE INVENTION

The compound semiconductor laser device of the present invention will be described below in detail based on an embodiment illustrated. In the following embodiment, an Al mole fraction, x, of an active layer in an AlGaAs semiconductor laser device is set to about 0.10 to 0.14, and an Al mole fraction, y, z, of a cladding layer is set to about 0.45 to 0.60, but the Al mole fractions can be set to any value satisfying the conditions that the Al mole fractions, x, y, z, of these layers are both 0 or more and that the Al mole fraction of the cladding layer is larger than that of the active layer.

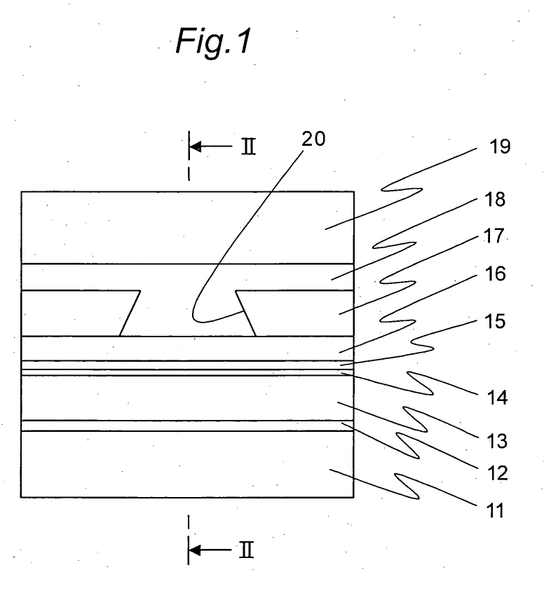

FIG. 1 shows a schematic cross sectional view of the structure of a compound semiconductor laser device according to one embodiment of the present invention.

The compound semiconductor laser device includes an n-type GaAs substrate 11, and an n-type GaAs buffer layer 12, an n-type Al_{y}Ga_{(1-y)}As first cladding layer 13, an n-type Al_{y}Ga_{(1-y)}As second cladding layer 14, a non-doped AlₓGa₍₁₋ₓ₎As active layer 15, a p-type Al_{y}Ga_{(1-y)}As third cladding layer 16, an n-type GaAs current block layer 17, a p-type Al_{z}Ga_{(1-z)}As fourth cladding layer 18 and a p-type GaAs cap layer 19 that are sequentially formed in this order on the n-type GaAs substrate 11. In this manner, the compound semiconductor laser device has a double-hetero structure.

The n-type Al_{y}Ga_{(1-y)}As second cladding layer 14 has a lower carrier concentration than that of the n-type Al_{y}Ga_{(1-y)}As first cladding layer 13. In more detail, Si, whose diffusion due to a thermal history is little, is used as an impurity added to the first and second cladding layers 13, 14, and the Si concentration of the first cladding layer 13 having a relatively high carrier concentration is set to 1×10¹⁸ cm⁻³−2×10¹⁸ cm⁻³, and the Si concentration of the second cladding layer 14 having a relatively low carrier concentration is set to 5×10¹⁷ cm⁻³ or less.

Mg is used as a p-type impurity added to the Al_{z}Ga_{(1-z)}As fourth cladding layer 18 and the p-type GaAs cap layer 19.

A lower portion of the Al_{z}Ga_{(1-z)}As fourth cladding layer 18 (i.e., a portion on the n-type GaAs substrate 11 side) has a ridge stripe shape.

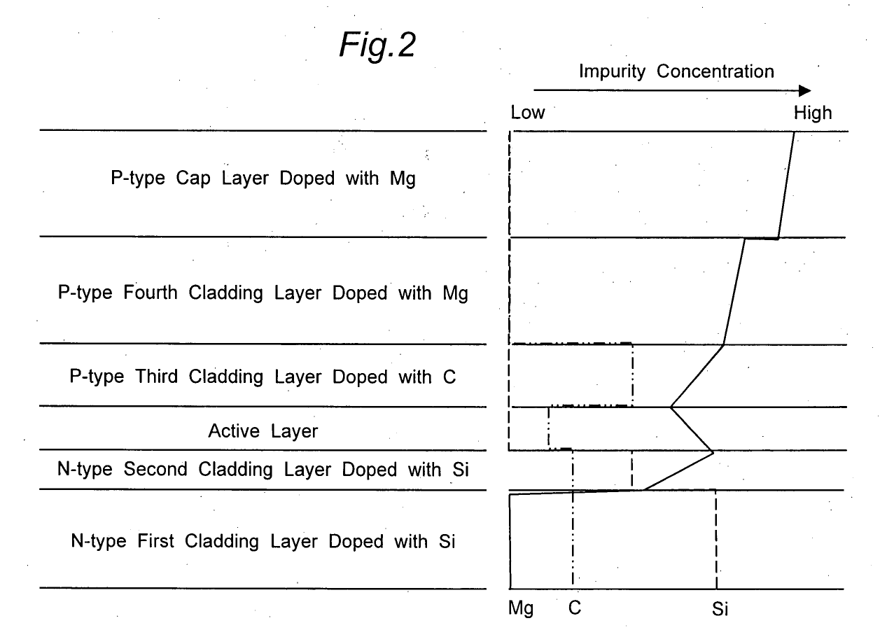

According to the compound semiconductor laser device with the above construction, the carrier concentration of the n-type Al_{y}Ga_{(1-y)}As second cladding layer 14 is lower than that of the n-type Al_{y}Ga_{(1-y)}As first cladding layer 13, whereby diffusion of Mg that is a p-type impurity, which occurs at the time of growth of the p-type Al_{z}Ga_{(1-z)}As fourth cladding layer 18 and the p-type GaAs cap layer 19, is controlled within the n-type second cladding layer 14 having the lower carrier concentration. Therefore, as shown in FIG. 2, the position of the pn junction is controlled by a steep impurity profile, so that variations in characteristics such as threshold current, operating current and operating voltage are suppressed.

The Si concentration of the n-type second cladding layer 14 close to the active layer 15 is set to 5×10¹⁷ cm⁻³ or lower, thereby making it possible to stably manufacture semiconductor laser devices having stable characteristics without causing trouble such as deterioration of reliability.

A method of fabricating the compound semiconductor laser device will be described below.

First, on an n-type GaAs substrate 11, an n-type GaAs buffer layer 12 is grown by the metal organic chemical vapor deposition (MOCVD) method, and then an n-type Al_{y}Ga_{(1-y)}As first cladding layer 13 (y=0.45 to 0.6, layer thickness: 1 μm) is grown. In the present embodiment, in growing the n-type Al_{y}Ga_{(1-y)}As first cladding layer 13 (y=0.45 to 0.6, layer thickness: 1 atm), disilane gas (Si₂H₆ (20 ppm), diluted by hydrogen) is added at a rate of 30 sccm (“sccm” is a unit to represent a volume flow rate at a temperature of 0° C. and a pressure of 1013.25 hPa and 30 sccm is equivalent to 5.001×10⁻⁴ L/s.) as a source gas for Si that is to be added as an n-type impurity. In the case of the n-type Al_{y}Ga_{(1-y)}As first cladding layer 13, growing at a growth temperature of 750° C. is performed, whereby the n-type Al_{y}Ga_{(1-y)}As first cladding layer 13 can obtain a carrier concentration of 1×10¹⁸ cm⁻³.

Next, an n-type Al_{y}Ga_{(1-y)}As second cladding layer 14 (y=0.45 to 0.6, layer thickness: 10 nm) is grown on the n-type Al_{y}Ga_{(1-y)}As first cladding layer 13. At this time, by adding disilane gas (Si₂H₆ (20 ppm), diluted by hydrogen) at a rate of 15 sccm (which is equivalent to 2.5005×10⁻⁴ L/s), the carrier concentration of the n-type Al_{y}Ga_{(1-y)}As second cladding layer 14 can be made 5×10¹⁷ cm⁻³.

Subsequently, on the n-type Al_{y}Ga_{(1-y)}As second cladding layer 14, a non-doped AlₓGa₍₁₋ₓ₎As active layer 15 (x=0.10 to 0.14, layer thickness: 0.08 μm), a p-type Al_{y}Ga_{(1-y)}As third cladding layer 16 (y=0.45 to 0.6, layer thickness: 0.35 μm, C concentration: 5×10¹⁷ cm⁻³), and an n-type GaAs current block layer 17 (layer thickness: 0.75 μm, Si concentration: 2×10¹⁸ cm⁻³) are grown in this order.

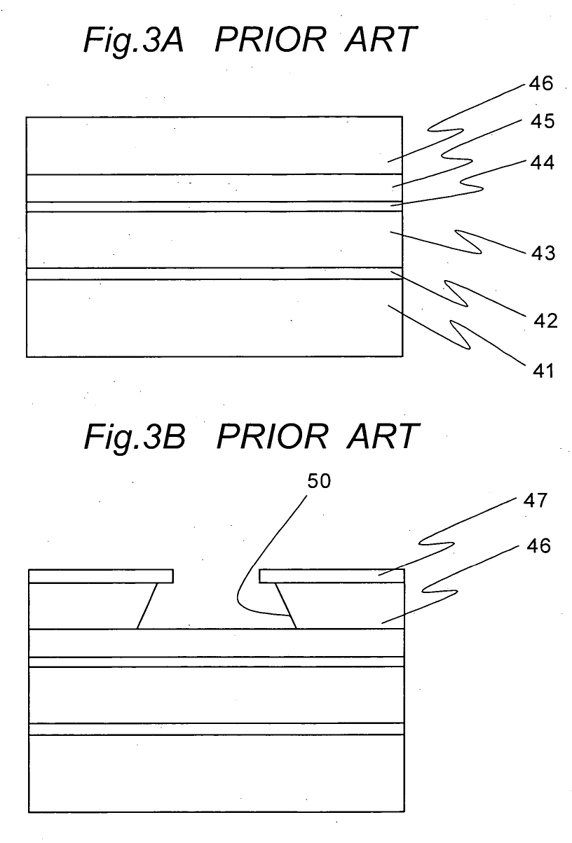

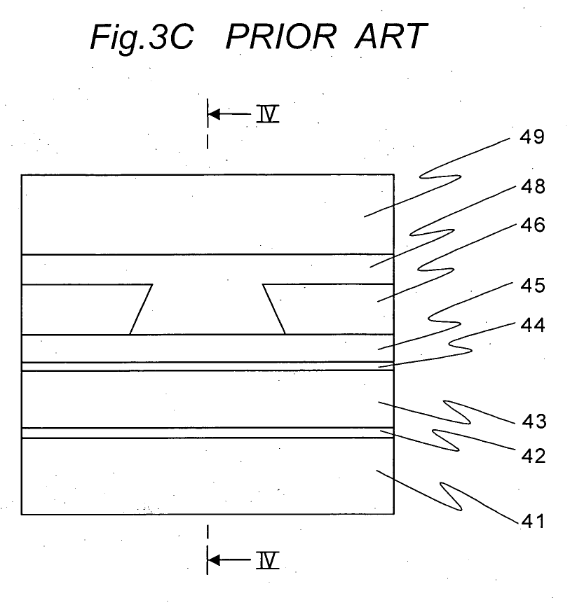

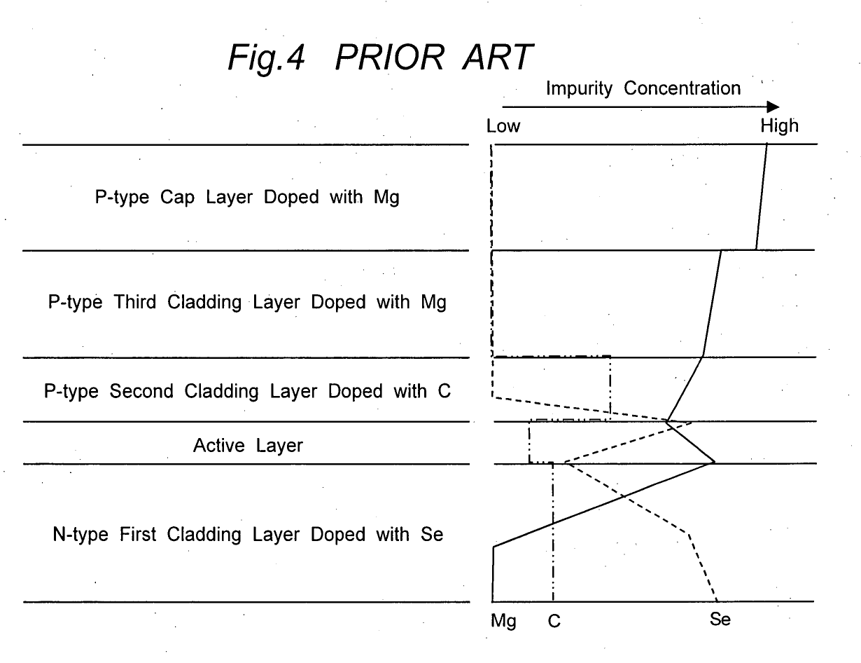

Subsequently, photolithography is performed in a manner similar to that shown in FIG. 3B so that an etching mask 47 having a stripe-like groove is formed on the n-type GaAs current block layer 17, and then the n-type GaAs current block layer 17 is etched using the etching mask 47. Thereby, a stripe-like and groove-like removed portion 20 is formed in the n-type GaAs current block layer 17.

Then, a p-type Al_{z}Ga_{(1-z)}As fourth cladding layer 18 in which Mg is used as a p-type impurity (z=0.45 to 0.60, layer thickness: 2 μm, Mg concentration: 1×10¹⁸ cm⁻³ to 2×10¹⁸ cm⁻³) and a p-type GaAs cap layer 19 (layer thickness: 50 μm, Mg concentration 6×10¹⁶ cm⁻³) are regrown by the LPE method.

As a result of the formation of the p-type Al_{z}Ga_{(1-z)}As fourth cladding layer 18 and the p-type GaAs cap layer 19, the impurity concentration in a portion of the p-type Al_{y}Ga_{(1-y)}As third cladding layer 16 opposite to the stripe-like and groove-like removed portion 20 becomes 1×10¹⁸ cm⁻³ due to the diffusion of Mg though the impurity concentration due to C in that portion was initially 5×10¹⁷ cm⁻³. Consequently, it is possible to inject current into the stripe efficiently as a semiconductor laser device, so that a low threshold and a low current driving are realized.

The impurity profile of the semiconductor laser device fabricated in this manner is similar to that shown in FIG. 2, that is, a steep impurity profile is obtained.

With regard to characteristics of semiconductor laser devices fabricated by the above method, with a cavity length of 200 μm, a threshold current of 28.0 mA, the operating current at an optical output power of 5 mW was 37.5 mA, and the operating voltage was 1.85 V, which means that favorable characteristics were obtained. Further, in an aging test of the devices at a device temperature of 80° C. and an optical output power of 7 mW, there was no device which increased in its threshold current value by 1.2 times or more within 48 hours, and no deterioration of reliability was observed.

Semiconductor laser devices having layer thicknesses of 50 nm, 70 nm, and 100 nm of the n-type Al_{y}Ga_{(1-y)}As second cladding layer 14 with the Si concentration therein being 5×10¹⁷ cm⁻³ were fabricated and evaluation of characteristics of these semiconductor laser devices was conducted, although in the above embodiment the layer thickness of the n-type Al_{y}Ga_{(1-y)}As second cladding layer 14 is 10 nm. The results of the evaluation of the characteristics are shown in Table 1 below.

TABLE 1

| | Operating current | | | | | |
|---|---|---|---|---|---|---|
| | Device No. | 1 | 2 | 3 | 4 | 5 |
| Layer | 50 nm | 37.7 mA | 38.1 mA | 38.3 mA | 38.3 mA | 38.9 mA |
| thickness | 70 nm | 40.8 mA | 40.9 mA | 41.5 mA | 41.3 mA | 42.0 mA |
| | 100 nm | 43.1 mA | 43.1 mA | 42.1 mA | 44.4 mA | 43.5 mA |

As is apparent from Table 1, the operating current value of semiconductor laser devices in which the layer thickness of the n-type Al_{y}Ga(l-y)As second cladding layer 14 was set to larger than 50 nm, specifically 70 nm or 100 nm, tended to increase, compared with semiconductor laser devices in which the layer thickness of the n-type Al_{y}Ga_{(1-y)}As second cladding layer 14 was set to 50 nm.

In contrast, in semiconductor laser devices in which the layer thickness of the n-type Al_{y}Ga_{(1-y)}As second cladding layer 14 was set to 5 nm, some devices stopped laser oscillation within 48 hours in the aging test at a device temperature of 80° C. and an optical output power of 7 mW, and deterioration of reliability was observed.

These results indicate that setting the layer thickness of the n-type Al_{y}Ga_{(1-y)}As second cladding layer 14 in a range of 10 nm to 50 nm makes it possible to fabricate semiconductor laser devices having good characteristics and reliability.

It should be noted that making the carrier concentration of the n-type Al_{y}Ga_{(1-y)}As first cladding layer 13 (y=0.45 to 0.6, layer thickness: 1 μm) higher than that of the p-type Al_{z}Ga_{(1-z)}As fourth cladding layer 18 (z=0.45 to 0.60, layer thickness: 2 μm, Mg concentration: 1×10¹⁸ cm⁻3 to 2×10¹⁸ cm⁻³) makes it possible to control the diffusion of Mg due to a thermal history during the LPE process.

Although the n-type Al_{y}Ga_{(1-y)}As second cladding layer 14 is in contact with the AlₓGa₍₁₋ₓ₎As active layer 15 in the above embodiment, an additional layer such as, for example, an optical guide layer may be provided between the n-type Al_{y}Ga_{(1-y)}As second cladding layer 14 and the AlₓGa₍₁₋ₓ₎As active layer 15. That is, the n-type Al_{y}Ga_{(1-y)}As second cladding layer 14 is to be formed in the vicinity of the AlₓGa₍₁₋ₓ₎As active layer 15.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A compound semiconductor laser device comprising:
a semiconductor substrate of first conduction type;
a first cladding layer of the first conduction type formed on the semiconductor substrate;
a second cladding layer of the first conduction type formed on the first cladding layer and having a carrier concentration lower than a carrier concentration of the first cladding layer;
an active layer formed on the second cladding layer; and
a third cladding layer of second conduction type formed on the active layer.

2. The compound semiconductor laser device according to claim 1, wherein the first conduction type is n-type, the second conduction type is p-type, and an impurity in the first cladding layer and the second cladding layer is Si.

3. The compound semiconductor laser device according to claim 1, wherein the carrier concentration of the first cladding layer is from 1×10¹⁸ cm⁻³ to 2×10¹⁸ cm⁻³, inclusive, and
the carrier concentration of the second cladding layer is from 1×10¹⁷ cm⁻³ to 5×10¹⁷ cm⁻³, inclusive.

4. The semiconductor laser device according to claim 1, wherein the second cladding layer has a layer thickness in a range of from 10 nm to 50 nm, inclusive.

5. The semiconductor laser device according to claim 1, wherein the second cladding layer is in proximity to the active layer.

6. The semiconductor laser device according to claim 1, further comprising:
a current block layer of the first conduction type formed on the third cladding layer and having a stripe-like and groove-like removed portion; and
a fourth cladding layer of the second conduction type formed on the current block layer.

7. The semiconductor laser device according to claim 1, wherein the semiconductor laser device is an AlGaAs-based semiconductor laser device.
